(19) United States
(12) Patent Application Publication
(10) Pub. No.: US 2024/0413270 A1
(43) Pub. Date: Dec. 12, 2024

(54) SEMICONDUCTOR LIGHT-EMITTING APPARATUS

(71) Applicant: NIKKISO CO., LTD., Tokyo (JP)

(72) Inventors: Izumi KIDA, Hakusan-shi Ishikawa (JP); Naoki SHIBATA, Hakusan-shi Ishikawa (JP); Tetsuhiko INAZU, Hakusan-shi Ishikawa (JP)

(21) Appl. No.: 18/733,434

(22) Filed: Jun. 4, 2024

(30) Foreign Application Priority Data
Jun. 9, 2023 (JP) 2023-095680

(51) Int. Cl. H01L 33/48; H01L 33/54; H01L 33/62

(52) U.S. Cl. CPC H01L 33/486; H01L 33/54; H01L 33/62

(57) ABSTRACT

A semiconductor light-emitting apparatus includes: a package substrate; a semiconductor light-emitting element flip-chip bonded on the package substrate; a frame body provided around the semiconductor light-emitting element on the package substrate; and a sealing member that covers the semiconductor light-emitting element on the package substrate, covers an upper surface of the frame body, and has translucency at an emission wavelength of the semiconductor light-emitting element. A height of the upper surface of the frame body is smaller than a height ha of an upper surface of the semiconductor light-emitting element.

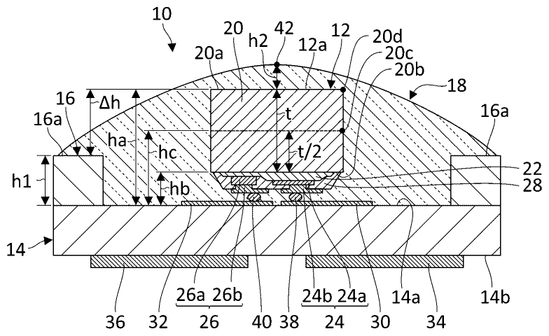

### RELATED APPLICATION

Priority is claimed to Japanese Patent Application No. 2023-095680, filed on Jun. 9, 2023, the entire content of which is incorporated herein by reference.

### BACKGROUND

### 1. Technical Field

The present disclosure relates to a semiconductor light-emitting apparatus.

### 2. Description of the Related Art

A semiconductor light-emitting apparatus in which a semiconductor light-emitting element bonded on a package substrate is sealed by a resin is known. For example, a technology for improving light extraction efficiency by forming the sealing resin in an upward convex dome shape has been proposed (see, for example, JP2017-59754A).

To form a sealing member in a dome shape, it is necessary to increase the thickness of the sealing member located above the semiconductor light-emitting element. Increasing the thickness of the sealing member increases a distortion caused by a difference in material between the sealing member and the package substrate with the result that the sealing member is easily exfoliated or cracked.

### SUMMARY

The present disclosure addresses the issue described above, and a purpose thereof is to provide a technology for improving the light extraction efficiency and the reliability of a semiconductor light-emitting apparatus.

A semiconductor light-emitting apparatus according to an embodiment of the present disclosure includes: a package substrate; a semiconductor light-emitting element flip-chip bonded on the package substrate; a frame body provided around the semiconductor light-emitting element on the package substrate; and a sealing member that covers the semiconductor light-emitting element on the package substrate, covers an upper surface of the frame body, and has translucency at an emission wavelength of the semiconductor light-emitting element. A height of the upper surface of the frame body is smaller than a height of an upper surface of the semiconductor light-emitting element.

### BRIEF DESCRIPTION OF THE DRAWINGS

The sole FIGURE is a cross sectional view schematically showing a configuration of a semiconductor light-emitting apparatus according to the embodiment.

### DETAILED DESCRIPTION

The invention will now be described by reference to the preferred embodiments. This does not intend to limit the scope of the present invention, but to exemplify the invention.

According to the present disclosure, the light extraction efficiency and the reliability of a semiconductor light-emitting apparatus can be improved.

A description will be given of an embodiment to practice the present disclosure with reference to the drawings. The numerals are used in the description to denote the same elements and a duplicate description is omitted as appropriate. To facilitate the understanding, the relative dimensions of the constituting elements in the drawings do not necessarily mirror the relative dimensions in the light-emitting element.

The FIGURE is a cross sectional view schematically showing a configuration of a semiconductor light-emitting apparatus 10 according to the embodiment. The semiconductor light-emitting apparatus 10 includes a semiconductor light-emitting element 12, a package substrate 14, a frame body 16, and a sealing member 18.

The semiconductor light-emitting element 12 is a semiconductor light-emitting element configured to emit ultraviolet light having a central wavelength A of approximately equal to or less than 360 nm. To output ultraviolet light having such a wavelength, an aluminum gallium nitride (AlGaN)-based semiconductor material having a band gap approximately equal to or more than 3.4 eV is used. In the embodiment, a deep ultraviolet-light emitting diode (DUV-LED) chip configured to emit deep ultraviolet light having a central wavelength A of about 240 nm-320 nm will be highlighted.

The semiconductor light-emitting element 12 includes a translucent substrate 20, a semiconductor layer 22, an anode electrode 24, a cathode electrode 26, and a protective layer 28.

The translucent substrate 20 is made of a material having translucency for the ultraviolet light emitted by the semiconductor light-emitting element 12. The light emitted by the semiconductor layer 22 is output outside the semiconductor light-emitting element 12 from the translucent substrate 20. The translucent substrate 20 is made of, for example, sapphire (Al₂O₃). The translucent substrate 20 includes an upper surface 20a and a lower surface 20b. The upper surface 20a and the lower surface 20b has, for example, a rectangular shape. The size of the upper surface 20a and the lower surface 20b is not limited to a particular size. For example, the upper surface 20a and the lower surface 20b are 1 mm by 1 mm in size. The thickness t of translucent substrate 20 from the upper surface 20a to the lower surface 20b is, for example, equal to or more than 100 μm, equal to or more than 200 μm, or equal to or more than 300 μm and is, for example, equal to or less than 1000 μm, equal to or less than 700 μm, or equal to or less than 500 μm.

The semiconductor layer 22 is provided below the translucent substrate 20 and is provided on the lower surface 20b of the translucent substrate 20. The semiconductor layer 22 includes, for example, an n-type semiconductor layer, an active layer, and a p-type semiconductor layer. The semiconductor layer 22 is made of an AlGaN-based semiconductor material. The AlGaN-based semiconductor material can be represented by a composition In_{1-x-y}AlₓGa_{y}N (0<x+y≤1, 0<x<1, 0<y<1). The semiconductor layer 22 is covered by the protective layer 28.

The anode electrode 24 includes a first contact electrode 24a and a first pad electrode 24b. The first contact electrode 24a is an internal electrode in contact with the semiconductor layer 22 and is in contact with the p-type semiconductor layer included in the semiconductor layer 22. The first contact electrode 24a is comprised of, for example, a metal layer made of Rh, etc. The first contact electrode 24a is covered by the protective layer 28. The first pad electrode 24b is an external electrode exposed outside the protective layer 28 and is electrically connected to the first contact electrode 24a via an opening provided in the protective layer 28. The first pad electrode 24b is comprised of a metal layer made of Ni/Au, etc.

The cathode electrode 26 includes a second contact electrode 26a and a second pad electrode 26b. The second contact electrode 26a is an internal electrode in contact with the semiconductor layer 22 and is in contact with the n-type semiconductor layer included in the semiconductor layer 22. The second contact electrode 26a is comprised of, for example, a metal layer made of Ti/Al, etc. The second contact electrode 26a is covered by the protective layer 28. The second pad electrode 26b is an external electrode exposed outside the protective layer 28 and is electrically connected to the second contact electrode 26a via an opening provided in the protective layer 28. The second pad electrode 26b is comprised of a metal layer made of Ni/Au, etc.

The protective layer 28 covers the semiconductor layer 22, the first contact electrode 24a, and the second contact electrode 26a. The protective layer 28 is made of a dielectric material such as oxide and nitride and is made of, for example, silicon oxide (SiO₂), aluminum oxide (Al₂O₃), silicon nitride (SiN), etc. The protective layer 28 may be comprised of a stack of a plurality of protective layers made of different materials.

The package substrate 14 has a flat plate shape, and has a bonding surface 14a and a back surface 14b. The package substrate 14 includes a first bonding electrode 30 and a second bonding electrode 32 provided on the bonding surface 14a. The package substrate 14 includes a first mounting electrode 34 and a second mounting electrode 36 provided on the back surface 14b. The first bonding electrode 30 is electrically connected to the first mounting electrode 34 inside the package substrate 14. The second bonding electrode 32 is electrically connected to the second mounting electrode 36 inside the package substrate 14. The package substrate 14 is made of, for example, an inorganic material, and is made of a ceramic material such as alumina (Al₂O₃), aluminum nitride (AlN), silicon nitride (SiN), and silicon carbide (SiC).

The semiconductor light-emitting element 12 is flip-chip bonded on the package substrate 14. The semiconductor light-emitting element 12 is bonded to the first bonding electrode 30 and the second bonding electrode 32. The semiconductor light-emitting element 12 is bonded to the package substrate 14 via a first bonding part 38 and a second bonding part 40. The first bonding part 38 is provided between the anode electrode 24 (the first pad electrode 24b) and the first bonding electrode 30 to connect the anode electrode 24 and the first bonding electrode 30 electrically. The second bonding part 40 is provided between the cathode electrode 26 (the second pad electrode 26b) and the second bonding electrode 32 to connect the cathode electrode 26 and the second bonding electrode 32 electrically.

The first bonding part 38 and the second bonding part 40 are, for example, stud bumps. The first bonding part 38 and the second bonding part 40 are formed by, for example, melting the tip of a metal wire made of Au, etc. to form a ball and pressing the ball against the first bonding electrode 30 and the second bonding electrode 32, respectively. The first bonding part 38 and the second bonding part 40 formed on the first bonding electrode 30 and the second bonding electrode 32 are respectively bonded to the anode electrode 24 (the first pad electrode 24b) and the cathode electrode 26 (the second pad electrode 26b) by, for example, ultrasonic bonding.

In a state where the semiconductor light-emitting element 12 is bonded to the package substrate 14, the height hb from the package substrate 14 (the bonding surface 14a) to the lower surface 20b of the translucent substrate 20 is, for example, smaller than the thickness t of the translucent substrate 20 and is, for example, smaller than half t/2 the thickness of the translucent substrate 20. The height hb from the package substrate 14 to the lower surface 20b of the translucent substrate 20 is, for example, equal to or less than 200 μm, equal to or less than 100 μm, equal to or less than 50 μm, or equal to or less than 30 μm. The height hb from the package substrate 14 to the lower surface 20b of the translucent substrate 20 is, for example, equal to or more than 10 μm, equal to or more than 15 μm, equal to or more than 20 μm, or equal to or more than 25 μm.

In a state where the semiconductor light-emitting element 12 is bonded to the package substrate 14, the height ha from the package substrate 14 (the bonding surface 14a) to the upper surface 12a of the semiconductor light-emitting element 12 (the upper surface 20a of the translucent substrate 20) is, for example, equal to or more than 100 μm, equal to or more than 200 μm, equal to or more than 300 μm, or equal to or more than 400 μm. The height ha from the package substrate 14 to the upper surface 12a of the semiconductor light-emitting element 12 is, for example, equal to or less than 1000 μm, equal to or less than 700 μm, equal to or less than 600 μm, or equal to or less than 500 μm.

The frame body 16 is provided around the semiconductor light-emitting element 12 on the package substrate 14. The frame body 16 is provided, for example, along the outer circumference of the package substrate 14 and over the entire circumference of the package substrate 14. The frame body 16 may be provided away from the outer circumference of the package substrate 14 or may be provided at a position displaced inward from the outer circumference of the package substrate 14. The shape of the frame body 16 revealed when an upper surface 16a of the frame body 16 is viewed is a rectangular shape and is, for example, a square shape. The shape of the frame body 16 revealed when the upper surface 16a of the frame body 16 is viewed may be a circular shape. The frame body 16 is made of, for example, the same material as that of the package substrate 14, and is integrally molded with the package substrate 14. The frame body 16 may be made of a material different from that of the package substrate 14. The frame body 16 may be molded as a body separate from the package substrate 14, or may be bonded to the bonding surface 14a of the package substrate 14 by any bonding material.

The frame body 16 has an upper surface 16a. The upper surface 16a of the frame body 16 is, for example, a flat surface. The height h1 of the upper surface 16a of the frame body 16 is smaller than the height ha of the upper surface 12a of the semiconductor light-emitting element 12 (the upper surface 20a of the translucent substrate 20). The height h1 from the package substrate 14 to the upper surface 16a of the frame body 16 is, for example, equal to or less than 80%, equal to or less than 70%, equal to or less than 60%, or equal to or less than 50% of the height ha from the package substrate 14 to the upper surface 12a of the semiconductor light-emitting element 12. The height h1 of the upper surface 16a of the frame body 16 is smaller than the height (intermediate height hc) at an intermediate position 20c where, for example, the thickness t of the translucent substrate 20 is halved (t/2). The height h1 of the upper surface 16a of the frame body 16 is larger than, for example, the height hb of the lower surface 20b of the translucent substrate 20. The height h1 from the package substrate 14 to the upper surface 16a of the frame body 16 is, for example, equal to or more than 20%, equal to or more than 30%, equal to or more than 40%, or equal to or more than 50% of the height ha from the package substrate 14 to the upper surface 12a of the semiconductor light-emitting element 12.

The height h1 of the upper surface 16a of the frame body 16 is, for example, equal to or more than 50 μm, equal to or more than 100 μm, equal to or more than 150 μm, or equal to or more than 200 μm. The height h1 of the upper surface 16a of the frame body 16 is, for example, equal to or less than 700 μm, equal to or less than 500 μm, equal to or less than 400 μm, or equal to or less than 300 μm. The difference Δh (=ha−h1) between the height h1 of the upper surface 16a of the frame body 16 and the height ha of the upper surface 12a of the semiconductor light-emitting element 12 is, for example, equal to or more than 50 μm, equal to or more than 100 μm, or equal to or more than 200 μm and is, for example, equal to or less than 500 μm, equal to or less than 400 μm, or equal to or less than 300 μm.

The sealing member 18 covers the semiconductor light-emitting element 12 on the package substrate 14. The sealing member 18 fills, for example, an area inside the frame body 16. The sealing member 18 covers the upper surface 16a of the frame body 16. The sealing member 18 is made of a material having translucency at the emission wavelength of the semiconductor light-emitting element 12. The sealing member 18 has an internal transmittance of equal to or more than 50%, and, preferably equal to or more than 70%, equal to or more than 80%, or equal to or more than 90% at the peak emission wavelength of the semiconductor light-emitting element 12. The sealing member 18 is made of a material having a lower refractive index than the translucent substrate 20. The sealing member 18 is made of, for example, a silicone resin or a fluororesin. The sealing member 18 may be made of an inorganic material such as quartz or a glass material instead of a resin. The sealing member 18 is configured not to contain, for example, a phosphor.

The sealing member 18 has, for example, a lens shape or a dome shape that is convex upward. An apex portion 42 of the sealing member 18 is, for example, located above the semiconductor light-emitting element 12 bonded to the package substrate 14. The sealing member 18 is formed to cover the entire upper surface 12a of the semiconductor light-emitting element 12 and cover a corner portion 20d forming the outer circumference of the upper surface 20a of the translucent substrate 20. The height h2 from the upper surface 12a of the semiconductor light-emitting element 12 to the apex portion 42 of the sealing member 18 is, for example, equal to or more than 50 μm, equal to or more than 100 μm, or equal to or more than 200 μm. The height h2 from the upper surface 12a of the semiconductor light-emitting element 12 to the apex portion 42 of the sealing member 18 is, for example, larger than half t/2 the thickness of the translucent substrate 20. The height h2 from the upper surface 12a of the semiconductor light-emitting element 12 to the apex portion 42 of the sealing member 18 is, for example, equal to or less than 500 μm, equal to or less than 400 μm, or equal to or less than 300 μm. The height h2 from the upper surface 12a of the semiconductor light-emitting element 12 to the apex portion 42 of the sealing member 18 is, for example, smaller than the height ha from the package substrate 14 to the upper surface 12a of the semiconductor light-emitting element 12 and is smaller than the thickness t of the translucent substrate 20. By reducing the height h2 of the sealing member 18 located above the semiconductor light-emitting element 12, the occurrence of exfoliation and cracks of the sealing member 18 can be suppressed.

According to this embodiment, the height h2 of the sealing member 18 covering the upper surface 12a of the semiconductor light-emitting element 12 can be reduced by configuring the height h1 of the upper surface 16a of the frame body 16 to be smaller than the height ha of the upper surface 12a of the semiconductor light-emitting element 12. Stated otherwise, the sealing member 18 covering the semiconductor light-emitting element 12 can be configured to have a dome shape, using a smaller amount of the sealing member 18, by reducing the height h1 of the upper surface 16a of the frame body 16. As a result, the occurrence of exfoliation and cracks of the sealing member 18 can be suppressed, and the reliability of the semiconductor light-emitting apparatus 10 can be improved.

According to this embodiment, the sealing member 18 is provided to cover the upper surface 16a of the frame body 16 so that the curvature of the upper surface of the sealing member 18 can be moderated as compared to a case where the sealing member 18 is not provided on the upper surface 16a of the frame body 16. This makes it possible to reduce the height h2 of the sealing member 18 covering the upper surface 12a of the semiconductor light-emitting element 12 and to configure the sealing member 18 covering the semiconductor light-emitting element 12 to have a dome shape, using a smaller amount of the sealing member 18. As a result, the occurrence of exfoliation and cracks of the sealing member 18 can be suppressed, and the reliability of the semiconductor light-emitting apparatus 10 can be improved.

According to this embodiment, the sealing member 18 is provided to cover the upper surface 16a of the frame body 16 so that it is easy to cover the entire semiconductor light-emitting element 12 by the sealing member 18 even if the thickness of the translucent substrate 20 is large and the height ha of the semiconductor light-emitting element 12 is large. As a result, the efficiency of light extraction from the translucent substrate 20 can be improved, and the light output of the semiconductor light-emitting apparatus 10 can be improved.

Given above is a description of the present disclosure based on the embodiment. The present disclosure is not restricted by the embodiment described above, and it will be understood by those skilled in the art that various design changes are possible and various modifications are possible and that such modifications are also within the scope of the present disclosure.

Some embodiments of the present disclosure will be described.

The first embodiment of the present disclosure relates to a semiconductor light-emitting apparatus including: a package substrate; a semiconductor light-emitting element flip-chip bonded on the package substrate; a frame body provided around the semiconductor light-emitting element on the package substrate; and a sealing member that covers the semiconductor light-emitting element on the package substrate, covers an upper surface of the frame body, and has translucency at an emission wavelength of the semiconductor light-emitting element, wherein a height of the upper surface of the frame body is smaller than a height of an upper surface of the semiconductor light-emitting element. According to the first embodiment, the light extraction efficiency of the semiconductor light-emitting apparatus can be improved by providing a translucent sealing member covering the semiconductor light-emitting element. Further, the height of the sealing member covering the upper surface of the semiconductor light-emitting element can be reduced by reducing the height of the upper surface of the frame body. Since a sealing member is also provided on the upper surface of the frame body, the curvature of the upper surface of the sealing member can be moderated, and the height of the sealing member covering the upper surface of the semiconductor light-emitting element can be reduced. The occurrence of exfoliation and cracks of the sealing member can be suppressed, and the reliability of the semiconductor light-emitting apparatus can be improved by reducing the height of the sealing member covering the upper surface of the semiconductor light-emitting element.

The second embodiment of the present disclosure relates to the semiconductor light-emitting apparatus according to the first embodiment, wherein a height from the package substrate to the upper surface of the frame body is 20% or more and 80% or less of a height from the package substrate to the upper surface of the semiconductor light-emitting element. According to the second embodiment, the curvature of the upper surface of the sealing member can be moderated, and the height of the sealing member covering the upper surface of the semiconductor light-emitting element can be reduced by configuring the height of the upper surface of the frame body to be 20% or more of the height of the semiconductor light-emitting element. Further, by configuring the height of the upper surface of the frame body to be 80% or less of the height of the semiconductor light-emitting element, the height of the sealing member covering the upper surface of the semiconductor light-emitting element can be reduced. The occurrence of exfoliation and cracks of the sealing member can be suppressed, and the reliability of the semiconductor light-emitting apparatus can be improved by reducing the height of the sealing member covering the upper surface of the semiconductor light-emitting element.

The third embodiment of the present disclosure relates to the semiconductor light-emitting apparatus according to the first or second embodiment, wherein a height from the upper surface of the semiconductor light-emitting element to an apex portion of the sealing member is smaller than a height from the package substrate to the upper surface of the semiconductor light-emitting element. According to the third embodiment, the occurrence of exfoliation and cracks of the sealing member can be suppressed, and the reliability of the semiconductor light-emitting apparatus can be improved by reducing the height of the sealing member covering the upper surface of the semiconductor light-emitting element.

The fourth embodiment of the present disclosure relates to the semiconductor light-emitting apparatus according to any one of the first through third embodiments, wherein the semiconductor light-emitting element includes an anode electrode and a cathode electrode bonded to the package substrate, a semiconductor layer on the anode electrode and the cathode electrode, and a translucent substrate on the semiconductor layer, and wherein the height of the frame body is larger than a height of a lower surface of the translucent substrate. According to the fourth embodiment, the height of the sealing member covering the upper surface of the semiconductor light-emitting element can be more suitably reduced, and the reliability of the semiconductor light-emitting apparatus can be improved by configuring the height of the upper surface of the frame body to be larger than the height of the lower surface of the translucent substrate.

The fifth embodiment of the present disclosure relates to the semiconductor light-emitting apparatus according to the fourth embodiment, wherein the height of the upper surface of the frame body is smaller than an intermediate height where a thickness of the translucent substrate is halved. According to the fifth embodiment, the height of the sealing member covering the upper surface of the semiconductor light-emitting element can be more suitably reduced, and the reliability of the semiconductor light-emitting apparatus can be improved by configuring the height of the upper surface of the frame body to be smaller than the intermediate height of the translucent substrate.

The sixth embodiment of the present disclosure relates to the semiconductor light-emitting apparatus according to the fourth or fifth embodiment, wherein a height from the upper surface of the semiconductor light-emitting element to an apex portion of the sealing member is smaller than a thickness of the translucent substrate. According to the sixth embodiment, the occurrence of exfoliation and cracks of the sealing member can be suppressed, and the reliability of the semiconductor light-emitting apparatus can be improved by configuring the height of the sealing member covering the upper surface of the semiconductor light-emitting element to be smaller than the thickness of the translucent substrate.

The seventh embodiment of the present disclosure relates to the semiconductor light-emitting apparatus according to any one of the fourth through sixth embodiments, wherein a thickness of translucent substrate is 300 μm or more and 500 μm or less. According to the seventh embodiment, the height of the sealing member covering the upper surface of the semiconductor light-emitting element can be reduced by providing a frame body having a small height even in the case the thickness of the translucent substrate is large. This suppresses the occurrence of exfoliation and cracks of the sealing member and improves the reliability of the semiconductor light-emitting apparatus.

What is claimed is:

1. A semiconductor light-emitting apparatus comprising:
a package substrate;
a semiconductor light-emitting element flip-chip bonded on the package substrate;
a frame body provided around the semiconductor light-emitting element on the package substrate; and
a sealing member that covers the semiconductor light-emitting element on the package substrate, covers an upper surface of the frame body, and has translucency at an emission wavelength of the semiconductor light-emitting element,
wherein a height of the upper surface of the frame body is smaller than a height of an upper surface of the semiconductor light-emitting element.

2. The semiconductor light-emitting apparatus according to claim 1,
wherein a height from the package substrate to the upper surface of the frame body is 20% or more and 80% or less of a height from the package substrate to the upper surface of the semiconductor light-emitting element.

3. The semiconductor light-emitting apparatus according to claim 1,
wherein a height from the upper surface of the semiconductor light-emitting element to an apex portion of the sealing member is smaller than a height from the package substrate to the upper surface of the semiconductor light-emitting element.

4. The semiconductor light-emitting apparatus according to claim 1,
wherein the semiconductor light-emitting element includes an anode electrode and a cathode electrode bonded to the package substrate, a semiconductor layer on the anode electrode and the cathode electrode, and a translucent substrate on the semiconductor layer, and
wherein the height of the frame body is larger than a height of a lower surface of the translucent substrate.

5. The semiconductor light-emitting apparatus according to claim 4,
wherein the height of the upper surface of the frame body is smaller than an intermediate height where a thickness of the translucent substrate is halved.

6. The semiconductor light-emitting apparatus according to claim 4,
wherein a height from the upper surface of the semiconductor light-emitting element to an apex portion of the sealing member is smaller than a thickness of the translucent substrate.

7. The semiconductor light-emitting apparatus according to claim 4,
wherein a thickness of translucent substrate is 300 μm or more and 500 μm or less.
